(19) United States
(12) Patent Application Publication
(10) Pub. No.: US 2025/0203956 A1
(43) Pub. Date: Jun. 19, 2025

(54) SPIN-ORBIT TORQUE MAGNETIC DEVICE CONTROLLED ON-OFF BASED ON ELECTRIC FIELD EFFECT

(71) Applicant: Daegu Gyeongbuk Institute of Science and Technology, Daegu (KR)

(72) Inventors: Soo Beom LEE, Daegu (KR); Chun Yeol YOU, Seoul (KR)

(73) Assignee: Daegu Gyeongbuk Institute of Science and Technology, Daegu (KR)

(21) Appl. No.: 18/701,715

(22) PCT Filed: Dec. 22, 2022
(86) PCT No.: PCT/KR2022/021087

§ 371 Date: Mar. 7, 2025

(30) Foreign Application Priority Data
Dec. 23, 2021 (KR) 10-2021-0185547

(51) Int. Cl. H10D 48/00

(52) U.S. Cl. CPC H10D 48/385

(57) ABSTRACT

The present invention relates to a spin-orbit torque magnetic device and a method of manufacturing the same. The spin-orbit torque magnetic device according to one embodiment may include a first heavy metal layer, a ferromagnetic layer formed on the first heavy metal layer, a second heavy metal layer formed on the ferromagnetic layer, and a gate oxide layer formed on the second heavy metal layer. Here, in the second heavy metal layer, when a gate voltage of a preset magnitude is applied to the gate oxide layer, the strength of spin-orbit interaction may be controlled.

### TECHNICAL FIELD

The present invention relates to a spin-orbit torque magnetic device, and more particularly, to a technical idea that controls the switching operation of a spin-orbit torque magnetic device based on the electric field effect.

### BACKGROUND ART

Spin-orbit interaction, which is a relativistic effect between the spin of an electron and the movement trajectory of the spin, enables mutual conversion of current and spin current. Materials with strong spin-orbit interaction include heavy metals such as platinum (Pt), tantalum (Ta), and tungsten (W). When current flows through these heavy metal nanowire structures, spin current flows in a direction perpendicular to the current direction.

When current is applied to a nanowire with a multilayer structure of a ferromagnetic substance and a heavy metal, spin current generated from the heavy metal is absorbed into the ferromagnetic substance, and at this time, the absorbed spin current acts as torque within the ferromagnetic substance, which is called spin-orbit torque.

Previously, spin-orbit torque has been studied with a focus on original technology such as magnetization reversal of a ferromagnetic layer and movement of a magnetic domain wall. Recently, based on this original technology, applications such as racetrack memory and spin torque majority function devices are being theoretically and experimentally examined.

Movement of the magnetic domain wall of a ferromagnetic layer using this spin-orbit torque occurs definitively when applied current exceeds a threshold. In complex magnetic domain wall circuits such as spin torque majority function devices, an additional switching system is required to precisely control input currents to limit the movement of a magnetic domain wall in a specific path.

As a result, the spin torque majority function device may have a complicated device structure. In addition, when an external switch is used, a signal-to-noise ratio may increase.

### DISCLOSURE

### Technical Problem

Therefore, the present invention has been made in view of the above problems, and it is one object of the present invention to provide a spin-orbit torque magnetic device capable of controlling electrical on/off of spin-orbit torque transmitted to a ferromagnetic substance using a layer structure of heavy metal/ferromagnetic substance/heavy metal and the electric field effect of a gate oxide layer and a method of manufacturing the spin-orbit torque magnetic device.

It is another object of the present invention to provide a spin-orbit torque magnetic device capable of limiting the movement of a magnetic domain wall in a specific path by controlling the electrical on/off of spin-orbit torque without an additional switching system and a method of manufacturing the spin-orbit torque magnetic device.

### Technical Solution

In accordance with one aspect of the present invention, provided is a spin-orbit torque magnetic device including a first heavy metal layer; a ferromagnetic layer formed on the first heavy metal layer; a second heavy metal layer formed on the ferromagnetic layer; and a gate oxide layer formed on the second heavy metal layer, wherein, in the second heavy metal layer, when a gate voltage of a preset magnitude is applied to the gate oxide layer, strength of spin-orbit interaction is controlled.

According to one aspect, the second heavy metal layer may be formed as an ultra-thin film with a thickness of 0.7 nm to 2 nm.

According to one aspect, the first heavy metal layer may include at least one of platinum (Pt), tantalum (Ta), and tungsten (W), and the second heavy metal layer may include platinum (Pt).

According to one aspect, when the first heavy metal layer includes platinum (Pt) and a gate voltage is not applied to the gate oxide layer, a spin direction of spin-orbit torque absorbed from the first heavy metal layer to the ferromagnetic layer and a spin direction of spin-orbit torque absorbed from the second heavy metal layer to the ferromagnetic layer may be opposite to each other, and the spin-orbit torque magnetic device may be electrically in an off state.

In addition, when the first heavy metal layer includes platinum (Pt) and a gate voltage is applied to the gate oxide layer, strength of spin-orbit torque absorbed from the second heavy metal layer to the ferromagnetic layer may be suppressed, and the spin-orbit torque magnetic device may be electrically in an on state.

According to one aspect, when the first heavy metal layer includes at least one of tantalum (Ta) and tungsten (W) and a gate voltage is not applied to the gate oxide layer, a spin direction of spin-orbit torque absorbed from the first heavy metal layer to the ferromagnetic layer and a spin direction of spin-orbit torque absorbed from the second heavy metal layer to the ferromagnetic layer may be identical to each other, and the spin-orbit torque magnetic device may be electrically in an on state.

In addition, when the first heavy metal layer includes at least one of tantalum (Ta) and tungsten (W) and a gate voltage is applied to the gate oxide layer, strength of spin-orbit torque absorbed from the second heavy metal layer to the ferromagnetic layer may be suppressed, and the spin-orbit torque magnetic device may be electrically an off state.

According to one aspect, the gate voltage may be a voltage corresponding to an electric field of 1×10 MV/cm to 2×10 MV/cm.

In accordance with another aspect of the present invention, provided is a spin torque majority function device including a plurality of input regions; an intersection region where the input regions intersect; and an output region formed to extend from the intersection region.

In the input regions, the intersection region, and the output region, a first heavy metal layer, a ferromagnetic layer, and a second heavy metal layer may be sequentially laminated. In the input regions, a gate oxide layer may be additionally formed on the second heavy metal layer. In the second heavy metal layer provided in the input regions, when a gate voltage of a preset magnitude is applied to the gate oxide layer, strength of spin-orbit interaction may be controlled.

According to one aspect, the second heavy metal layer may be formed as an ultra-thin film with a thickness of 0.7 nm to 2 nm.

According to one aspect, the first heavy metal layer may include at least one of platinum (Pt), tantalum (Ta), and tungsten (W), and the second heavy metal layer may include platinum (Pt).

In accordance with yet another aspect of the present invention, provided is a method of manufacturing a spin-orbit torque magnetic device, the method including a step of forming a first heavy metal layer on a substrate; a step of forming a ferromagnetic layer on the first heavy metal layer; a step of forming a second heavy metal layer on the ferromagnetic layer; and a step of forming a gate oxide layer on the second heavy metal layer, wherein, in the second heavy metal layer, when a gate voltage of a preset magnitude is applied to the gate oxide layer, strength of spin-orbit interaction is controlled.

According to one aspect, in the step of forming the second heavy metal layer, the second heavy metal layer may be formed as an ultra-thin film with a thickness of 0.7 nm to 2 nm.

According to one aspect, in the step of forming the first heavy metal layer, the first heavy metal layer including at least one of platinum (Pt), tantalum (Ta), and tungsten (W) may be formed on the substrate.

In addition, in the step of forming the second heavy metal layer, the second heavy metal layer including platinum (Pt) may be formed on the ferromagnetic layer.

### Advantageous Effects

According to one embodiment, the present invention can control the electrical on/off of spin-orbit torque transmitted to a ferromagnetic substance using a layer structure of heavy metal/ferromagnetic substance/heavy metal and the electric field effect of a gate oxide.

According to one embodiment, the present invention can limit the movement of a magnetic domain wall in a specific path by controlling the electrical on/off of spin-orbit torque without an additional switching system.

### DESCRIPTION OF DRAWINGS

FIG. 1 is a diagram explaining a spin-orbit torque magnetic device according to one embodiment.

FIGS. 2A and 2B are diagrams explaining the switching operation of a spin-orbit torque magnetic device having a first heavy metal layer based on platinum.

FIGS. 3A and 3B are diagrams explaining the switching operation of a spin-orbit torque magnetic device having a first heavy metal layer based on at least one of tantalum and tungsten.

FIG. 4 is a diagram explaining an application example of the spin-orbit torque magnetic device according to one embodiment.

FIG. 5 is a flowchart explaining a method of manufacturing a spin-orbit torque magnetic device according to one embodiment.

### BEST MODE

Hereinafter, various embodiments of the present invention are described with reference to the attached drawings.

However, it should be understood that the present invention is not limited to the embodiments according to the concept of the present invention, but includes changes, equivalents, or alternatives falling within the spirit and scope of the present invention.

In the following description of the present invention, detailed description of known functions and configurations incorporated herein will be omitted when it may make the subject matter of the present invention unclear.

In addition, the terms used in the specification are defined in consideration of functions used in the present invention, and can be changed according to the intent or conventionally used methods of clients, operators, and users. Accordingly, definitions of the terms should be understood on the basis of the entire description of the present specification.

In description of the drawings, like reference numerals may be used for similar elements.

The singular expressions in the present specification may encompass plural expressions unless clearly specified otherwise in context.

In this specification, expressions such as “A or B” and “at least one of A and/or B” may include all possible combinations of the items listed together.

Expressions such as “first” and “second” may be used to qualify the elements irrespective of order or importance, and are used to distinguish one element from another and do not limit the elements.

It will be understood that when an element (e.g., first) is referred to as being “connected to” or “coupled to” another element (e.g., second), the first element may be directly connected to the second element or may be connected to the second element via an intervening element (e.g., third).

As used herein, “configured to” may be used interchangeably with, for example, “suitable for”, “ability to”, “changed to”, “made to”, “capable of”, or “designed to” in terms of hardware or software.

In some situations, the expression “device configured to” may mean that the device “may do ˜” with other devices or components.

For example, in the sentence “processor configured to perform A, B, and C”, the processor may refer to a general purpose processor (e.g., CPU or application processor) capable of performing corresponding operation by running a dedicated processor (e.g., embedded processor) for performing the corresponding operation, or one or more software programs stored in a memory device.

In addition, the expression “or” means “inclusive or” rather than “exclusive or”.

That is, unless mentioned otherwise or clearly inferred from context, the expression “x uses a or b” means any one of natural inclusive permutations.

In the above-described specific embodiments, elements included in the invention are expressed in singular or plural in accordance with the specific embodiments shown.

It should be understood, however, that the singular or plural representations are to be chosen as appropriate to the situation presented for the purpose of description and that the above-described embodiments are not limited to the singular or plural constituent elements. The constituent elements expressed in plural may be composed of a single number, and constituent elements expressed in singular form may be composed of a plurality of elements.

In addition, the present invention has been described with reference to exemplary embodiments, but it should be understood that various modifications may be made without departing from the scope of the present invention.

Therefore, the scope of the present invention should not be limited by the embodiments, but should be determined by the following claims and equivalents to the following claims.

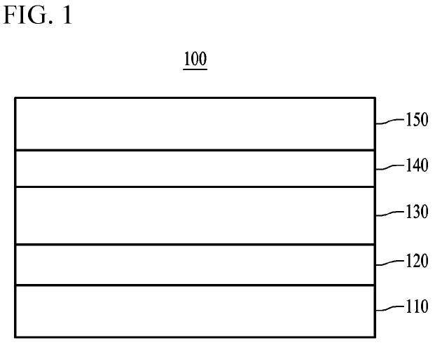

FIG. 1 is a diagram explaining a spin-orbit torque magnetic device according to one embodiment.

Referring to FIG. 1, the spin-orbit torque magnetic device 100 according to one embodiment may include a first heavy metal layer 120, a ferromagnetic layer 130 formed on the first heavy metal layer 120, a second heavy metal layer 140 formed on the ferromagnetic layer 130, and a gate oxide layer 150 formed on the second heavy metal layer 140. Here, the first heavy metal layer 120, the ferromagnetic layer 130, the second heavy metal layer 140, and the gate oxide layer 150 may be formed on a substrate 110.

In addition, in the second heavy metal layer 140 according to one embodiment, when a gate voltage of a preset magnitude is applied to the gate oxide layer 150, the strength of spin-orbit interaction may be controlled.

For example, the second heavy metal layer 140 may be formed as an ultra-thin film with a thickness of 0.7 nm to 2 nm, and the gate voltage may be a voltage corresponding to an electric field of 1×10 MV/cm to 2×10 MV/cm.

In addition, the gate oxide layer 150 may be replaced with a material with a high dielectric constant or an ionic organic material.

According to one aspect, the first heavy metal layer 120 may include at least one of platinum (Pt), tantalum (Ta), and tungsten (W), and the second heavy metal layer 140 may include platinum (Pt).

According to one aspect, when the first heavy metal layer 120 includes platinum (Pt) and a gate voltage is not applied to the gate oxide layer 150, the spin direction of the spin-orbit torque absorbed from the first heavy metal layer 120 to the ferromagnetic layer 130 and the spin direction of the spin-orbit torque absorbed from the second heavy metal layer 140 to the ferromagnetic layer 130 are opposite to each other. In this case, the spin-orbit torque magnetic device 100 may be electrically in an off state.

In addition, when the first heavy metal layer 120 includes platinum (Pt) and a gate voltage is applied to the gate oxide layer 150, the strength of the spin-orbit torque absorbed from the second heavy metal layer 140 to the ferromagnetic layer 130 is suppressed. In this case, the spin-orbit torque magnetic device 100 may be electrically in an on state.

According to one aspect, when the first heavy metal layer 120 includes at least one of tantalum (Ta) and tungsten (W) and a gate voltage is not applied to the gate oxide layer 150, the spin direction of the spin-orbit torque absorbed from the first heavy metal layer 120 to the ferromagnetic layer 130 and the spin direction of the spin-orbit torque absorbed from the second heavy metal layer 140 to the ferromagnetic layer 130 are the same. In this case, the spin-orbit torque magnetic device 100 may be electrically in an on state.

In addition, when the first heavy metal layer 120 includes at least one of tantalum (Ta) and tungsten (W) and a gate voltage is applied to the gate oxide layer 150, the strength of the spin-orbit torque absorbed from the second heavy metal layer 140 to the ferromagnetic layer 130 is suppressed. In this case, the spin-orbit torque magnetic device 100 may be electrically in an off state.

That is, the spin-orbit torque magnetic device 100 may perform a switching operation similar to that of an NMOS transistor when the first heavy metal layer is platinum (Pt), and may perform a switching operation similar to that of a PMOS transistor when the first heavy metal layer is tantalum (Ta) or tungsten (W).

According to an embodiment, a spin-orbit torque magnetic device whose the first heavy metal layer is platinum (Pt) and a spin-orbit torque magnetic device whose the first heavy metal layer is tantalum (Ta) or tungsten (W) may be connected to each other to implement a magnetic device that performs operations similar to those of a CMOS switching device.

Specifically, in the spin-orbit torque magnetic device 100, platinum (Pt) having strong spin-orbit interaction may be used as a material for the second heavy metal layer 140. To induce an electric field effect by applying an external electric field, the gate oxide layer 150 with a high dielectric constant may be deposited on the second heavy metal layer 140.

The electric field effect is a phenomenon that mainly appears in semiconductors where the density of carriers (electrons or holes) inherent in a material is low. In general, the electric field effect has been almost ignored in metals due to the high electron density thereof and the resulting Coulomb shielding phenomenon.

However, when a strong electric field is applied to platinum (Pt) in the form of an ultra-thin film of 2 nm or less using an ionic liquid, the electrical resistance of platinum (Pt), which is a metallic material, changes due to the electric field effect. Here, the ionic liquid means that cations and anions do not form crystals and exist in a liquid phase.

For example, platinum (Pt) in the form of an ultra-thin film has an fcc crystal structure, an atomic size of about 0.19 nm, and a crystal constant of about 0.34 nm, so when only one layer of the fcc crystal structure is flat, the platinum (Pt) in the form of an ultra-thin film may be implemented to have a minimum thickness of about 0.7 nm.

More specifically, in the second heavy metal layer 140 based on platinum (Pt) with a thickness of 0.7 nm to 2 nm, when a gate voltage corresponding to an electric field of 1×10 MV/cm to 2×10 MV/cm is applied through the gate oxide layer 150, current due to the inverse spin hall effect may be suppressed to 1 nA or less.

That is, in the second heavy metal layer 140 based on a platinum (Pt) ultra-thin film, spin-orbit interaction may be suppressed depending on whether a strong electric field is applied. In this way, the switching operation of the spin-orbit torque magnetic device 100 may be controlled.

In addition, an electric field of 1×10 MV/cm to 2×10 MV/cm may be applied to the gate oxide layer 150 from an external controller.

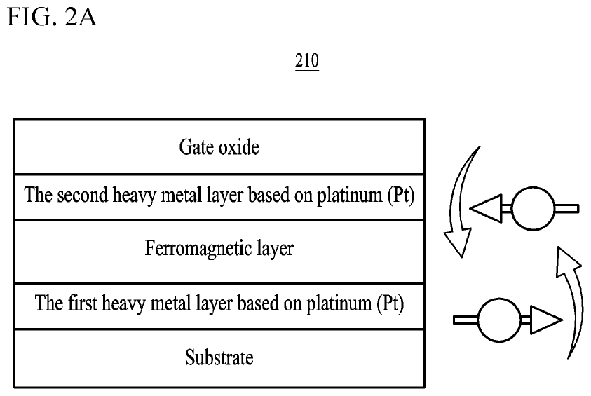

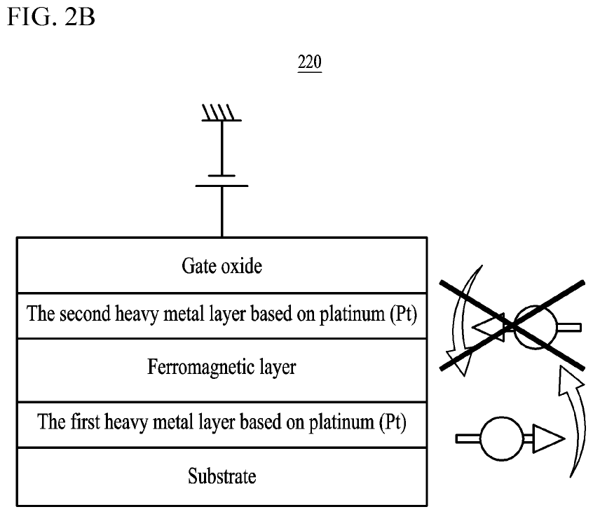

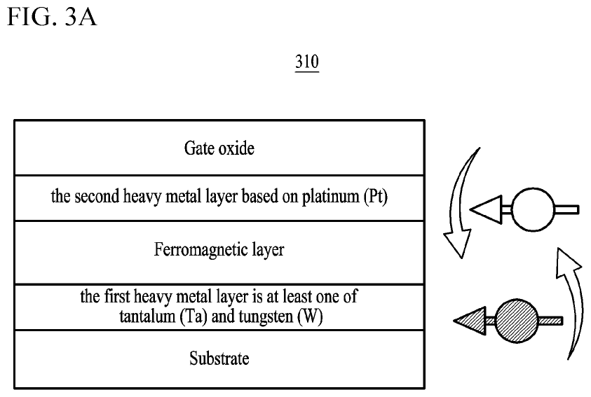

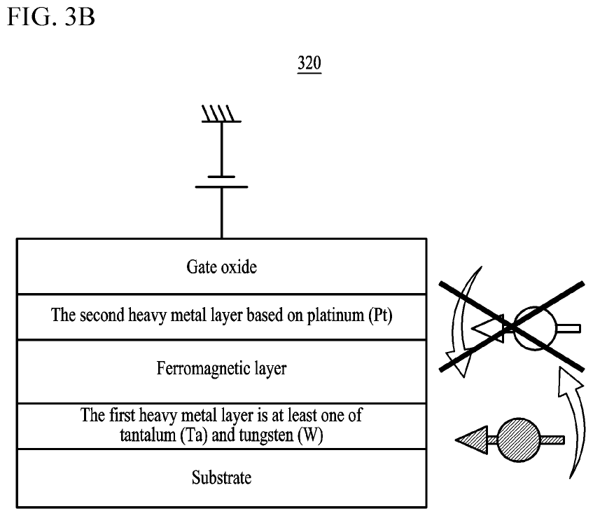

The switching operation of the spin-orbit torque magnetic device 100 according to one embodiment will be described in detail with reference to FIGS. 2A to 3B.

FIGS. 2A and 2B are diagrams explaining the switching operation of a spin-orbit torque magnetic device having a first heavy metal layer based on platinum.

Referring to FIGS. 2A and 2B, a spin-orbit torque magnetic device according to one embodiment may include a first heavy metal layer based on platinum (Pt), a ferromagnetic layer, a second heavy metal layer based on platinum (Pt), and a gate oxide layer sequentially laminated on the substrate. For example, the second heavy metal layer may be formed to have a thickness of 0.7 nm to 2 nm.

Specifically, as shown in drawing number 210, when the first and second heavy metal layers are platinum (Pt) and a gate voltage is not applied through the gate oxide layer, the spin direction of the spin-orbit torque absorbed from the first heavy metal layer to the ferromagnetic layer and the spin direction of the spin-orbit torque absorbed from the second heavy metal layer to the ferromagnetic layer are opposite to each other. In this case, the spin-orbit torque magnetic device may be electrically in an off state.

That is, in the spin-orbit torque magnetic device, since the directions of spins absorbed from the first and second heavy metal layers to the ferromagnetic layer are opposite to each other, actual torque applied to the ferromagnetic layer may be ‘0’.

Specifically, the spin direction of spin-orbit torque is determined by the direction of current flowing in a heavy metal nanowire and the extrinsic direction of the direction of spin current. That is, when current is applied to a nanowire with a symmetrical layer structure of platinum/ferromagnetic layer/platinum, the sign of the torque transmitted from the platinum layer to the ferromagnetic layer is opposite, so the spin-orbit torque may be canceled out and disappear.

As shown in drawing number 220, when the first and second heavy metal layers are platinum (Pt) and a gate voltage of a certain size (for example, 1.5 V to 2 V) is applied through the gate oxide layer, the spin-orbit torque absorbed from the second heavy metal layer to the ferromagnetic layer is suppressed. In this case, the spin-orbit torque magnetic device may be electrically in an on state.

That is, when a gate voltage is applied through the gate oxide layer, the spin-orbit interaction of the second heavy metal layer is suppressed, and the spin-orbit torque applied to the ferromagnetic layer is only contributed by the first heavy metal layer. Thus, the spin-orbit torque magnetic device may be controlled to a preset first level size.

Specifically, in the spin-orbit torque magnetic device, when a gate voltage is applied to the gate oxide layer and an electric field effect is induced, the spin-orbit interaction of the second heavy metal layer adjacent to the gate oxide is suppressed. Accordingly, as in the conventional spin-orbit torque systems, only the spin-orbit torque from the first heavy metal layer may be transferred to the ferromagnetic layer.

That is, the spin-orbit torque magnetic device may control the strength of the spin-orbit torque applied to the ferromagnetic layer by applying a gate voltage. Through this control, the switching operation of the spin-orbit torque magnetic device (on state: the spin-orbit torque of the first level, off state: the spin-orbit torque of ‘0’ level) may be controlled.

FIGS. 3A and 3B are diagrams explaining the switching operation of a spin-orbit torque magnetic device having a first heavy metal layer based on at least one of tantalum and tungsten.

Referring to FIGS. 3A and 3B, a spin-orbit torque magnetic device according to one embodiment may include a first heavy metal layer based on tantalum (Ta) or tungsten (W), a ferromagnetic layer, a second heavy metal layer based on platinum (Pt), and a gate oxide layer sequentially laminated on a substrate. For example, the second heavy metal layer may be formed to have a thickness of 0.7 nm to 2 nm.

Specifically, as shown in drawing number 310, when the first heavy metal layer is at least one of tantalum (Ta) and tungsten (W), the second heavy metal layer is platinum (Pt), and a gate voltage is not applied through the gate oxide layer, the spin direction of the spin-orbit torque absorbed from the first heavy metal layer to the ferromagnetic layer and the spin direction of the spin-orbit torque absorbed from the second heavy metal layer to the ferromagnetic layer are the same. In this case, the spin-orbit torque magnetic device may be electrically in an on state.

That is, in the spin-orbit torque magnetic device, since the spin directions absorbed from each of the first and second heavy metal layers to the ferromagnetic layer are the same, the ferromagnetic layer may be controlled with a strong torque, that is, the size of a preset second level (second level>first level).

Specifically, tantalum (Ta) and tungsten (W) are heavy metal materials with strong spin-orbit interaction like platinum (Pt), but the sign of current-spin current conversion efficiency of tantalum (Ta) and tungsten (W) is negative. Thus, a spin-orbit torque of the opposite sign to that of platinum (Pt) may be generated.

As shown in drawing number 320, when the first heavy metal layer is at least one of tantalum (Ta) and tungsten (W), the second heavy metal layer is platinum (Pt), and a gate voltage of a certain size (for example, 1.5 V to 2 V) is applied through the gate oxide layer, the strength of the spin-orbit torque absorbed from the second heavy metal layer to the ferromagnetic layer is suppressed. In this case, the spin-orbit torque magnetic device may be electrically in an off state.

That is, when a gate voltage is applied through the gate oxide layer, the spin-orbit interaction of the second heavy metal layer is suppressed, and the spin-orbit torque applied to the ferromagnetic layer is only contributed by the first heavy metal layer. Thus, the spin-orbit torque magnetic device may be controlled to a size of a first level.

Specifically, in the spin-orbit torque magnetic device, when a gate voltage is applied to the gate oxide layer and an electric field effect is induced, the spin-orbit interaction of the second heavy metal layer adjacent to the gate oxide is suppressed. Accordingly, as in the conventional spin-orbit torque systems, only the spin-orbit torque from the first heavy metal layer may be transferred to the ferromagnetic layer.

That is, the spin-orbit torque magnetic device may control the strength of the spin-orbit torque applied to the ferromagnetic layer by applying a gate voltage. Through this control, the switching operation of the spin-orbit torque magnetic device (on state: the spin-orbit torque of the second level, off state: the spin-orbit torque of the first level) may be controlled.

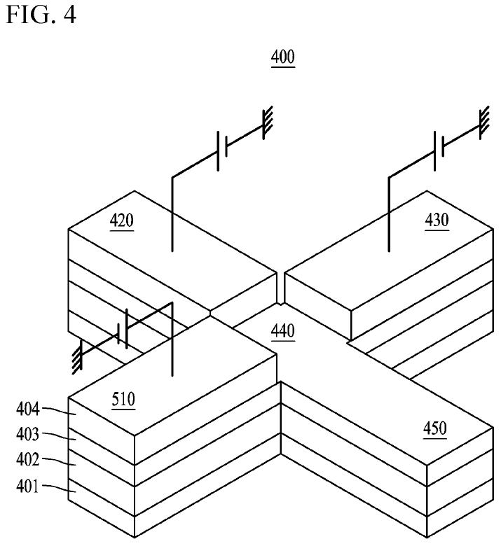

FIG. 4 is a diagram explaining an application example of the spin-orbit torque magnetic device according to one embodiment.

That is, FIG. 4 shows an application example of the spin-orbit torque magnetic device according to one embodiment described in FIGS. 1 to 3B. Hereinafter, among content explained with reference to FIG. 4, content that overlaps with the content explained with reference to FIGS. 1 to 3B will be omitted.

Referring to FIG. 4, the spin-orbit torque magnetic device according to one embodiment may be applied as a spin torque majority function device 400.

The spin torque majority function device 400 according to one embodiment may include a plurality of input regions 410, 420, and 430, an intersection region 440 where the input regions intersect, and an output region 450 extending from the intersection region 440.

Specifically, in the spin torque majority function device 400, magnetic domain walls, which are information carriers, may be generated and transmitted from the three input regions 410, 420, and 430, and the transmitted magnetic domain walls may be merged in the intersection region 440 and transmitted to the output region 450. At this time, movement of the magnetic domain walls may be caused by spin-orbit torque caused by current flowing in a first heavy metal layer 401 and a second heavy metal layer 403.

More specifically, in the spin torque majority function device 400, when current flows through the magnetic domain walls formed in the input regions 410, 420, and 430, as electrons pass through magnetic domain walls, adjacent magnetization may change due to the spin transfer torque. At this time, when current exceeds a predetermined threshold, the magnetic domain walls may move along a ferromagnetic layer 402 along the direction of electron movement.

For example, in the spin torque majority function device 400, when signals (that is, magnetization direction) input through a first input region 410, a second input region 420, and a third input region 430 all correspond to a logic value ‘1’, the signal (that is, magnetization direction) corresponding to the logic value ‘1’ may be output through the output region 450.

In addition, in the spin torque majority function device 400, when a signal input through any one of the first input region 410, the second input region 420, and the third input region 430 corresponds to a logical value ‘0’, and signals input through the remaining two input regions correspond to a logic value ‘1’, the signals corresponding to the logic value ‘1’ may be output through the output region 450.

In addition, in the spin torque majority function device 400, when a signal input through any one of the first input region 410, the second input region 420, and the third input region 430 corresponds to a logical value ‘1’, and signals input through the remaining two input regions correspond to a logic value ‘0’, the signals corresponding to the logic value ‘0’ may be output through the output region 450.

In addition, in the input regions 410, 420, and 430, the intersection region 440, and the output region 450 according to one embodiment, the first heavy metal layer 401, the ferromagnetic layer 402, and the second heavy metal layer 403 may be sequentially laminated. In the input regions 410, 420, and 430, a gate oxide layer 404 may be further formed on the second heavy metal layer 403.

In addition, when a gate voltage of a preset magnitude is applied to the gate oxide layer 404, the strength of spin-orbit interaction of the second heavy metal layer 403 provided in the input regions 410, 420, and 430 may be controlled.

For example, the second heavy metal layer 403 may be formed as an ultra-thin film with a thickness of 0.7 nm to 2 nm, and the gate voltage may be 1.5 V to 2 V.

According to one aspect, the first heavy metal layer 401 may include at least one of platinum (Pt), tantalum (Ta), and tungsten (W), and the second heavy metal layer 403 may include platinum (Pt).

According to one aspect, when the first heavy metal layer 401 includes platinum (Pt) and a gate voltage is not applied to the gate oxide layer 404, the spin direction of the spin-orbit torque absorbed from the first heavy metal layer 401 to the ferromagnetic layer 402 and the spin direction of the spin-orbit torque absorbed from the second heavy metal layer 403 to the ferromagnetic layer 402 are opposite to each other. In this case, the input regions 410, 420, and 430 may be electrically in an off state.

In addition, when the first heavy metal layer 401 includes platinum (Pt) and a gate voltage is applied to the gate oxide layer 404, the strength of the spin-orbit torque absorbed from the second heavy metal layer 403 to the ferromagnetic layer 402 is suppressed. In this case, the input regions 410, 420, and 430 may be electrically in an on state.

According to one aspect, when the first heavy metal layer 401 includes at least one of tantalum (Ta) and tungsten (W) and a gate voltage is not applied to the gate oxide layer 404, the spin direction of the spin-orbit torque absorbed from the first heavy metal layer 401 to the ferromagnetic layer 402 and the spin direction of the spin-orbit torque absorbed from the second heavy metal layer 403 to the ferromagnetic layer 402 are the same. In this case, the input regions 410, 420, and 430 may be electrically in an on state.

In addition, when the first heavy metal layer 401 includes at least one of tantalum (Ta) and tungsten (W) and a gate voltage is applied to the gate oxide layer 404, the strength of the spin-orbit torque absorbed from the second heavy metal layer 403 to the ferromagnetic layer 402 is suppressed. In this case, the input regions 410, 420, and 430 may be electrically in an off state.

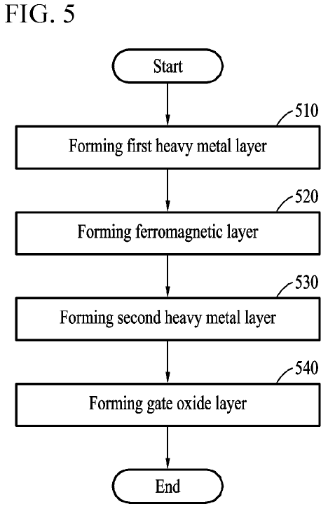

FIG. 5 is a flowchart explaining a method of manufacturing a spin-orbit torque magnetic device according to one embodiment.

That is, FIG. 5 explains a method of manufacturing the spin-orbit torque magnetic device according to one embodiment described in FIGS. 1 to 4. Hereinafter, among content explained with reference to FIG. 5, content that overlaps with the content explained with reference to FIGS. 1 to 4 will be omitted.

Referring to FIG. 5, according to the method of manufacturing the spin-orbit torque magnetic device according to one embodiment, in step 510, a first heavy metal layer may be formed on a substrate.

According to one aspect, according to the method of manufacturing the spin-orbit torque magnetic device according to one embodiment, in step 520, in the step of forming a first heavy metal layer, the first heavy metal layer including at least one of platinum (Pt), tantalum (Ta), and tungsten (W) may be formed on the substrate.

Next, according to the method of manufacturing the spin-orbit torque magnetic device according to one embodiment, in step 520, a ferromagnetic layer may be formed on the first heavy metal layer.

Next, according to the method of manufacturing the spin-orbit torque magnetic device according to one embodiment, in step 530, a second heavy metal layer may be formed on the ferromagnetic layer.

According to one aspect, according to the method of manufacturing the spin-orbit torque magnetic device according to one embodiment, in step 530, in the step of forming a second heavy metal layer, the second heavy metal layer may be formed as an ultra-thin film with a thickness of 0.7 nm to 2 nm.

In addition, according to the method of manufacturing the spin-orbit torque magnetic device according to one embodiment, in step 530, the second heavy metal layer including platinum (Pt) may be formed on the ferromagnetic layer.

Next, according to the method of manufacturing the spin-orbit torque magnetic device according to one embodiment, in step 540, a gate oxide layer may be formed on the second heavy metal layer.

In addition, in the second heavy metal layer, when a gate voltage of a preset magnitude is applied to the gate oxide, the strength of spin-orbit interaction may be controlled.

According to one aspect, when the first heavy metal layer includes platinum (Pt) and a gate voltage is not applied to the gate oxide layer, the spin direction of the spin-orbit torque absorbed from the first heavy metal layer to the ferromagnetic layer and the spin direction of the spin-orbit torque absorbed from the second heavy metal layer 140 to the ferromagnetic layer are opposite to each other. In this case, the spin-orbit torque magnetic device may be electrically in an off state.

In addition, when the first heavy metal layer includes platinum (Pt) and a gate voltage is applied to the gate oxide layer, the strength of the spin-orbit torque absorbed from the second heavy metal layer to the ferromagnetic layer is suppressed. In this case, the spin-orbit torque magnetic device may be electrically in an on state.

According to one aspect, when the first heavy metal layer includes at least one of tantalum (Ta) and tungsten (W) and a gate voltage is not applied to the gate oxide layer, the spin direction of the spin-orbit torque absorbed from the first heavy metal layer to the ferromagnetic layer and the spin direction of the spin-orbit torque absorbed from the second heavy metal layer to the ferromagnetic layer are the same. In this case, the spin-orbit torque magnetic device may be electrically in an on state.

In addition, when the first heavy metal layer includes at least one of tantalum (Ta) and tungsten (W) and a gate voltage is applied to the gate oxide layer, the strength of the spin-orbit torque absorbed from the second heavy metal layer to the ferromagnetic layer is suppressed. In this case, the spin-orbit torque magnetic device may be electrically in an off state.

That is, when the first heavy metal layer is platinum (Pt), the spin-orbit torque magnetic device may perform a switching operation like an NMOS transistor. When the first heavy metal layer is tantalum (Ta), the spin-orbit torque magnetic device may perform a switching operation like a PMOS transistor.

That is, the present invention may control the electrical on/off of spin-orbit torque transmitted to a ferromagnetic substance using a layer structure of heavy metal/ferromagnetic substance/heavy metal and the electric field effect of a gate oxide.

In addition, the present invention may limit the movement of a magnetic domain wall in a specific path by controlling the electrical on/off of spin-orbit torque without an additional switching system.

Specifically, in a one-dimensional nanowire structure, the movement of the above-mentioned magnetic domain walls may be controlled in an on/off manner by turning input current on or off. However, in a high-dimensional magnetic domain wall circuit that uses magnetic domain walls as information carriers and targets logical operations, such as a spin torque majority function device, when designing a device, since the current density for device operation is optimized, input current is always fixed and controlling the movement of magnetic domain walls is not easy.

On the other hand, when the present invention is used, spin-orbit torque transmitted to a ferromagnetic substance may be controlled electrically. In addition, the present invention may be used in spintronic logic devices that use movement of magnetic domain walls.

In addition, in a spin torque majority function device, since three input currents intersect at an intersection and flow as one output current, device design for optimal operation is required. That is, controlling spin-orbit torque using modulation of input current affects current density at an output terminal and may not generate sufficient spin-orbit torque.

On the other hand, when the present invention is used, the spin-orbit torque of input terminals and the resulting movement of magnetic domain walls may be electrically controlled while maintaining input current.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

1. A spin-orbit torque magnetic device, comprising:
a first heavy metal layer;
a ferromagnetic layer formed on the first heavy metal layer;
a second heavy metal layer formed on the ferromagnetic layer; and
a gate oxide layer formed on the second heavy metal layer,
wherein, in the second heavy metal layer, when a gate voltage of a preset magnitude is applied to the gate oxide layer, strength of spin-orbit interaction is controlled.

2. The spin-orbit torque magnetic device according to claim 1, wherein the second heavy metal layer is formed as an ultra-thin film with a thickness of 0.7 nm to 2 nm.

3. The spin-orbit torque magnetic device according to claim 1, wherein the first heavy metal layer comprises at least one of platinum (Pt), tantalum (Ta), and tungsten (W), and the second heavy metal layer comprises platinum (Pt).

4. The spin-orbit torque magnetic device according to claim 3, wherein, when the first heavy metal layer comprises platinum (Pt) and a gate voltage is not applied to the gate oxide layer, a spin direction of spin-orbit torque absorbed from the first heavy metal layer to the ferromagnetic layer and a spin direction of spin-orbit torque absorbed from the second heavy metal layer to the ferromagnetic layer are opposite to each other, and the spin-orbit torque magnetic device is electrically in an off state, and
when the first heavy metal layer comprises platinum (Pt) and a gate voltage is applied to the gate oxide layer, strength of spin-orbit torque absorbed from the second heavy metal layer to the ferromagnetic layer is suppressed, and the spin-orbit torque magnetic device is electrically in an on state.

5. The spin-orbit torque magnetic device according to claim 3, wherein, when the first heavy metal layer comprises at least one of tantalum (Ta) and tungsten (W) and a gate voltage is not applied to the gate oxide layer, a spin direction of spin-orbit torque absorbed from the first heavy metal layer to the ferromagnetic layer and a spin direction of spin-orbit torque absorbed from the second heavy metal layer to the ferromagnetic layer are identical to each other, and the spin-orbit torque magnetic device is electrically in an on state, and
when the first heavy metal layer comprises at least one of tantalum (Ta) and tungsten (W) and a gate voltage is applied to the gate oxide layer, strength of spin-orbit torque absorbed from the second heavy metal layer to the ferromagnetic layer is suppressed, and the spin-orbit torque magnetic device is electrically an off state.

6. The spin-orbit torque magnetic device according to claim 1, wherein the gate voltage is a voltage corresponding to an electric field of 1×10 MV/cm to 2×10 MV/cm.

7. A spin torque majority function device, comprising:
a plurality of input regions;
an intersection region where the input regions intersect; and
an output region formed to extend from the intersection region,
wherein, in the input regions, the intersection region, and the output region, a first heavy metal layer, a ferromagnetic layer, and a second heavy metal layer are sequentially laminated,
in the input regions, a gate oxide layer is additionally formed on the second heavy metal layer, and
in the second heavy metal layer provided in the input regions, when a gate voltage of a preset magnitude is applied to the gate oxide layer, strength of spin-orbit interaction is controlled.

8. The spin torque majority function device according to claim 7, wherein the second heavy metal layer is formed as an ultra-thin film with a thickness of 0.7 nm to 2 nm.

9. The spin torque majority function device according to claim 7, wherein the first heavy metal layer comprises at least one of platinum (Pt), tantalum (Ta), and tungsten (W), and the second heavy metal layer comprises platinum (Pt).

10. A method of manufacturing a spin-orbit torque magnetic device, comprising:
a step of forming a first heavy metal layer on a substrate;
a step of forming a ferromagnetic layer on the first heavy metal layer;
a step of forming a second heavy metal layer on the ferromagnetic layer; and
a step of forming a gate oxide layer on the second heavy metal layer,
wherein, in the second heavy metal layer, when a gate voltage of a preset magnitude is applied to the gate oxide layer, strength of spin-orbit interaction is controlled.

11. The method according to claim 10, wherein, in the step of forming the second heavy metal layer, the second heavy metal layer is formed as an ultra-thin film with a thickness of 0.7 nm to 2 nm.

12. The method according to claim 11, wherein, in the step of forming the first heavy metal layer, the first heavy metal layer comprising at least one of platinum (Pt), tantalum (Ta), and tungsten (W) is formed on the substrate, and
in the step of forming the second heavy metal layer, the second heavy metal layer comprising platinum (Pt) is formed on the ferromagnetic layer.
